(19) United States
(12) Patent Application Publication
(10) Pub. No.: US 2007/0019691 A1
(43) Pub. Date: Jan. 25, 2007

(54) Waveguide laser light source suitable for projection displays

(75) Inventors: Holger Mönch, Vaals (NL); Gero Heusler, Aachen (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/569,717

(22) PCT Filed: Aug. 20, 2004
(86) PCT No.: PCT/IB04/51516

§ 371 Date: Feb. 24, 2006

(30) Foreign Application Priority Data
Aug. 29, 2003 (EP) 03102678.4

(51) Int. Cl. H01S 3/10; H01S 5/00; H01S 3/08

(52) U.S. Cl. 372/22; 372/21; 372/99; 372/50.1

(57) ABSTRACT

The invention relates to a semiconductor diode laser used to pump a waveguide and their use as light source. A waveguide laser (15) according to the present invention producing visible wavelength radiation from IR wavelength radiation comprising: a) at least one semiconductor diode laser or diode laser bar (8) producing IR wavelength radiation; b) at least one upconversion layer (13a, 13b, 13c) having a thickness of at least 1 μm thicker than the thickness of the emitting layer in the semiconductor diode laser that converts the IR wavelength radiation into visible wavelengths by an upconversion process of photon absorption energy transfer followed by emission; c) at least one optical resonator which recirculates the visible wavelength radiation and/or at least one optical resonator which recirculates the IR wavelength radiation; whereby—the laser diode or laser diode bar and the upconversion layer(s) are arranged on the same substrate or each on a separate substrate (12, 14);—the laser diode or laser diode bar and the upconversion layer(s) are adjacent arranged, whereby a gap between the adjacent arranged diode laser bar and the upconversion layer(s) is formed; or—the laser diode or laser diode bar and the upconversion layer(s) are contacting arranged in this order, and whereby the waveguide laser has a beam quality M2 of ≧2 and ≦1000.

The invention relates to diode laser pumped waveguide lasers and their use as light source for replacement of a conventional arc lamp, in particular to upconversion waveguide lasers. Waveguide lasers of the present invention can be used as light source to replace conventional arc lamps such as for projection displays as well as for various lighting applications, e.g. headlight, shop, home, accent, spot or theater lighting.

A laser diode is a semiconductor device that produces coherent radiation in which the waves are all at the same frequency and phase in the visible or infrared IR) spectrum when current passes through it. Waveguide lasers comprise a laser diode as a pump source and a waveguide structure in which the pump radiation of the diode laser is absorbed and converted to a different wavelength. Laser diodes and waveguide lasers are used in optical fiber systems, compact disc (CD), as pump source for solid state lasers, laser printers, remote-control devices, intrusion detection systems and for material processing like welding or cutting.

U.S. Pat. No. 5,436,919 discloses a multi wavelength upconversion waveguide laser producing visible or ultraviolet wavelength radiation comprising a semiconductor laser diode producing relatively long wavelength radiation, a channel waveguide having a thin film material which converts the relatively long wavelength radiation into visible or ultraviolet wavelength radiation, and an optical resonator which recirculates the visible or ultraviolet wavelength radiation. The optical resonator may use an output optical coating or one or more Bragg grating reflectors as an output coupler. One or more optical resonators may be used to produce one or more visible or ultraviolet radiation wavelengths. One or more independently controllable light wave modulators are used to modulate the visible or ultraviolet wavelength radiation. It is disclosed in U.S. Pat. No. 5,436,919 that the thin film material has a thickness of 0.7 μm to 2.0 μm.

Thus diode lasers and in addition upconversion waveguide lasers are generally known in prior art.

However, there exists a long need to simplify the manufacture process of waveguide lasers, in order to provide said waveguide laser with a low vertical range of manufacture, a small number of components, increased robustness, improved compactness and low costs, in order to provide a light source which has ray performance superior or comparable with arc lamps so that said waveguide laser can be used as light source having better or similar radiation performance to replace arc lamps.

It is the object of this invention to overcome the above drawbacks by providing a waveguide laser having a similar radiation performance to arc lamps. The waveguide laser light source of the present invention is easier to produce, more compact, and more similar to arc lamps compared with laser diodes known in prior art.

This object is achieved in a waveguide laser producing visible wave-length radiation from IR wavelength radiation comprising: a) at least one semiconductor diode laser or laser bar producing IR wavelength radiation; b) at least one upconversion layer that converts the IR wavelength radiation into visible wavelengths by an upconversion process of photon absorption energy transfer followed by emission; c) at least one optical resonator which recirculates the visible wavelength radiation and/or at least one optical resonator which recirculates the IR wavelength radiation; whereby—the thickness of the upconversion layer is at least 1 μm thicker than the thickness of the emitting layer in the semiconductor diode laser;—the laser diode or laser diode bar and the upconversion layer are arranged on the same substrate or each on a separate substrate;—the laser diode or laser diode bar and the upconversion layer are adjacent arranged, whereby a gap between the adjacent arranged diode laser or diode laser bar and the upconversion layer is formed; or—the laser diode or laser diode bar and the upconversion layer are contacting arranged; and whereby the diode laser has an optical beam quality M2 of ≦2 and ≧1000.

This object can also be achieved in a waveguide laser producing visible wavelength radiation from IR wavelength radiation comprising: a) at least one semiconductor diode laser or laser bar producing IR wavelength radiation; b) at least one upconversion layer that converts the IR wavelength radiation into visible wavelengths by an upconversion process of photon absorption energy transfer followed by emission; c) at least two waveguide layers that carry the IR wavelength radiation; d) at least one optical resonator which recirculates the visible wavelength radiation and/or at least one optical resonator which recirculates the IR wavelength radiation; whereby
the upconversion layer is placed between two waveguide layers of a refractive index smaller than the refractive index of the upconversion layer;
the total thickness of the upconversion layer and the two waveguide layers is at least 1 μm thicker than the thickness of the emitting layer in the semiconductor diode laser
the laser diode or laser diode bar and the upconversion layer are arranged on the same substrate or each on a separate substrate;
the laser diode or laser diode bar and the upconversion layer are adjacent arranged, whereby a gap between the adjacent arranged diode laser or diode laser bar and the upconversion layer is formed; or
the laser diode or laser diode bar and the upconversion layer are contacting arranged; and whereby the diode laser has an optical beam quality M² of ≧2 and ≦1000.

It has been surprisingly found by the inventors that an upconversion waveguide laser can be adapted to have similar radiation performance to arc lamps in that the optical beam quality M² is adjusted to ≧2 and ≦1000. This is achieved in that the thickness of the upconversion layer is at least 1 μm thicker than the thickness of the emitting layer in the semiconductor diode laser.

The term “optical resonator” as used in the present descriptions comprises at least two mirrors which recirculate the visible wavelength radiation and/or which recirculates the IR wavelength radiation.

The term “emitting layer” as used in the present descriptions means the layers in a laser diode or a laser diode bar that carry the laser light and determine the size of the lasing spot of each single emitter. These layers comprise in a typical laser diode two waveguide layers sandwiching a quantum-well structure with a typical overall thickness of at least 1 μm for IR laser diodes.

The term “upconversion layer” as used in the present descriptions means a layer structure that consists preferably of a rare earth doped ZBLAN layer, e.g. ZBLAN: Er that carries the incoupled IR light and the visible light emitted by the rare earth ions by an upconversion process of photon absorption energy transfer followed by emission. The upconversion layer can be placed between two layers of lower refractive index, e.g. consisting of ZBLAN with a different stoichiometric composition. Also, the upconversion layer can be placed between two waveguide layers of lower refractive index, e.g. consisting of ZBLAN with a different stoichiometric composition, that in turn can be placed between two layers of lower refractive index than the waveguide layer, e.g. consisting of ZBLAN with a stoichiometric composition differing from the upconversion layer and the waveguide layer.

The thickness of the upconversion layer or, respectively, the total thickness of the upconversion layer and the two waveguide layers, can be of at least 2.1 μm, preferably of at least 2.5 μm and more preferably of at least 3 μm. Further, the thickness of the upconversion layer or, respectively, the total thickness of the upconversion layer and the two waveguide layers, can be of at least 3.5 μm or of at least 4 μm or of at least 5 μm or of at least 6 μm.

The term “waveguide layer” as used in the present description means a layer that consists preferably of undoped ZBLAN and carries the incoupled IR light, but not the visible light or only a minor fraction of the visible light.

In case a waveguide laser of the present invention comprises a laser diode then the thickness of the upconversion layer or, respectively, the total thickness of the upconversion layer and the two waveguide layers, is at least 1 μm thicker than the thickness of the adjacent emitting layer of the laser diode.

In case a waveguide laser of the present invention comprises a laser diode bar then the thickness of the each upconversion layer or, respectively, the total thickness of the upconversion layer and the two waveguide layers, is at least 1 μm thicker than the thickness of each adjacent emitting layer of the adjacent laser diode bar.

In case a waveguide laser of the present invention comprises a laser diode stack then the thickness of the upconversion layer or, respectively, the total thickness of the upconversion layer and the two waveguide layers, is at least 1 μm thicker than the thickness of each adjacent emitting layer of the adjacent laser diode stack.

Preferably, the waveguide laser according to the present invention has an optical beam quality M² of ≧2 and ≦1000, also preferably of ≧2.5 and ≦200, further preferably of ≧3 and ≦150, more preferably of ≧3.5 and ≦100, most preferably of ≧4 and ≦50.

Projection display systems have high demands on the light source, therefore UHP lamps are generally used, i.e. short arc high pressure discharge lamps. It has now been surprisingly found by the inventors that the waveguide laser of the present invention can be used instead of arc lamps for projection displays. Further, the number of optical components in such a projection system becomes redundant when using a laser light source of the present invention instead of an arc lamp. Furthermore, the waveguide laser of the present invention preferably has an optical conversion efficiencies of more than 5%, preferably of more than 7% and more preferably of more than 10%. The optical conversion efficiency is the ratio of the visible light output of the waveguide laser to the electric power input to the laser diode or laser diode bar.

The thickness of the upconversion layer or, respectively, the total thickness of the upconversion layer and the two waveguide layers, is at least 1 μm more than the thickness of the emitting layer in the semiconductor diode laser and converts the IR wavelength radiation into visible wavelengths by an upconversion process of photon absorption energy transfer followed by emission may consist of a fluoride glass known as ZBLAN, consisting of the components ZrF₄, BaF₂, LaF₃, AlF₃ and NaF, doped with one or more rare earth ions from the group Er, Yb, Pr, Tm, Ho, Dy, Eu, Nd or a combination thereof or one of the crystals LiLuF₄, LiYF₄, BaY₂F₈, SrF₂, LaCl₃, KPb₂Cl₅, LaBr₃ doped with one or more rare earth ions as above or a rare earth doped metal fluoride such as Ba-Ln-F or Ca-Ln-F, where Ln is one or more rare earth ions as above ZBLAN materials are further described in K. Ohsawa, T. Shibita, Preparation and characterization of ZrF₄—BaF₂—LaF₃—NaF—AlF₃ glass optical fibers, Journal of Lightwave Technology LT-2 (5), 602 (1984).

For example, the upconversion layer may consist of a glass layer of Er doped ZBLAN deposited on a ZBLAN layer on a copper substrate. Alternatively, the upconversion layer may consist of Yb, Er doped ZBLAN. According to the present invention rare earth metals comprising in the group of Er, Ho, Nd, Pr, Pr/Yb and/or Tm are preferred. However, production techniques to make such upconversion layers are generally known in the art. Rare earth doped metals which can be used for upconversion layers according to the present invention are disclosed e.g. in U.S. Pat. No. 6,510,276 B1.

A conventional semiconductor IR laser diode serves as an optical pump. The semiconductor laser diode should operate at a wavelength between 790 nm and 1150 nm. It is recognized that other rare earth dopants may require different pump wavelengths. The power requirements will vary according to the upconversion layer. Preferably, the IR output powers of a diode laser bar or stack used according to the present invention can be ≧20 W, more preferably ≧50 W. The IR output power of a single laser diode should be ≧1 W, more preferably ≧2 W.

According to the present invention at least one frequency-converting layer consisting of an upconversion layer and optional of at least one optical resonator which recirculates the visible wavelength radiation is in contact with the IR diode laser or diode laser bar or diode laser stack. In more detail, the IR wavelength radiation of the IR diode laser or diode laser bar or stack is upconverted by means of rare-earth doped upconversion layer, e.g. glass or crystal layer, which are positioned in front of the diode laser or diode laser bar.

An IR diode laser or diode laser bar or stack and an upconversion layer can be placed on the same substrate or on separate substrates. The substrate can be of glass material and/or ceramic and/or metal, e.g. copper, preferably the substrate is of a material with high heat conductivity to allow efficient cooling of the device.

According to a first embodiment of the present invention an IR diode laser or diode laser bar arranged on a substrate is sandwiched between one n-electrode and one p-electrode. The upconversion layer is arranged on the same substrate positioned adjacent in front of the IR diode laser or laser bar. The visible laser can be realized in the form of an intracavity or extracavity arrangement. In the case of an extracavity arrangement, the laser diode or the laser diode bar comprises a mirror with a high reflectivity for the desired IR wavelength on the one side and an outcoupling mirror as known in the art on the other side where the upconversion layer is located. These mirrors are typically realized as dichroic coatings on the end facets of the diode laser or diode laser bar. A second resonator is formed by two mirrors at both ends of the upconversion layer structure. One mirror placed between the IR diode laser and the upconversion layer structure is highly reflective at the desired visible wavelength, the other mirror at the end of the device serves as the outcoupling mirror as known in the art. These mirrors can also be realized in the form of dichroic coatings. In the case of an intracavity arrangement, the IR output mirror is placed at the end of the device, i.e. at the end of the upconversion layer. In this case, the mirror may comprise a high reflectivity for the desired IR wavelength. In case of an intracavity arrangement of an IR diode laser, i.e. no IR mirror is placed between the IR diode laser and the upconversion layer, it is preferred that a mirror reflective for visible wavelength radiation but transmissive for IR wavelength radiation is placed between the IR diode laser bar or stack and the upconversion layer at the side of the upconversion layer.

According to a second embodiment of the present invention an IR diode laser or diode laser bar is arranged on a first substrate and is sandwiched between one n-electrode and one p-electrode. The upconversion layer is arranged on a second substrate positioned in front of the IR diode laser or laser bar. The visible laser can be realized in the form of an intracavity or extracavity arrangement. In the case of an extracavity arrangement, the laser diode or the laser diode bar comprises a mirror with a high reflectivity for the desired IR wavelength on the one side and an outcoupling mirror as known in the art on the other side where the upconversion layer is located. These mirrors are typically realized as dichroic coatings on the end facets of the diode laser or diode laser bar. A second resonator is formed by two mirrors at both ends of the upconversion layer structure. One mirror placed between the IR diode laser and the upconversion layer structure is highly reflective at the desired visible wavelength, the other mirror at the end of the device serves as the outcoupling mirror as known in the art. These mirrors can also be realized in the form of dichroic coatings. In the case of an intracavity arrangement, the IR output mirror is placed at the end of the device, i.e. at the end of the upconversion layer. In this case, the mirror may comprise a high reflectivity for the desired IR wavelength. In case of an intracavity arrangement of an IR diode laser, i.e. no IR mirror is placed between the IR diode laser and the upconversion layer, it is preferred that a mirror reflective for visible wavelength radiation but transmissive for IR wavelength radiation is placed between the IR diode laser bar or stack and the upconversion layer at the side of the upconversion layer.

According to the present invention a waveguide laser light source can comprise at least 1, preferably at least 5, more preferably at least 10, most preferably at least 20 diode laser emitters, i.e. one laser diode bar.

Alternatively, a waveguide laser light source according to the present invention can comprise:

a stack of more than one semiconductor diode laser bar producing IR wavelength radiation; and comprising an upconversion layer that converts the IR wavelength radiation into visible wavelengths by an upconversion process of photon absorption energy transfer followed by emission as described above.

A waveguide laser light source according to present invention may have a gap between the adjacent arranged diode laser or diode laser bar and the upconversion layer of ≧0 μm and ≦10 μm. However, it is preferred that between the adjacent arranged diode laser or diode laser bar, mirror material of at least one optical resonator and upconversion layer no gap is formed. If a gap is formed between the adjacent arranged diode laser bar, mirror material of at least one optical resonator and the upconversion layer the gap is preferably filled with a filling material, such as an index-matching liquid or gel known in the art.

The gap can be of ≧0.1 μm and ≦9 μm, preferably ≧0.2 μm and ≦8 μm, further preferably ≧0.3 μm and ≦7.0 μm, also preferably ≧0.5 μm and ≦6.0 μm and more preferably ≧0.7 μm and ≦6.0 μm. However, the gap can be of ≧0.4 μm and ≦5 μm, or ≧0.8 μm and ≦4 μm, or ≧0.9 μm and ≦3.0 μm, or ≧1.0 μm and ≦2.0 μm.

Exemplary embodiments of the present invention will be described in the following, with reference to the following drawings:

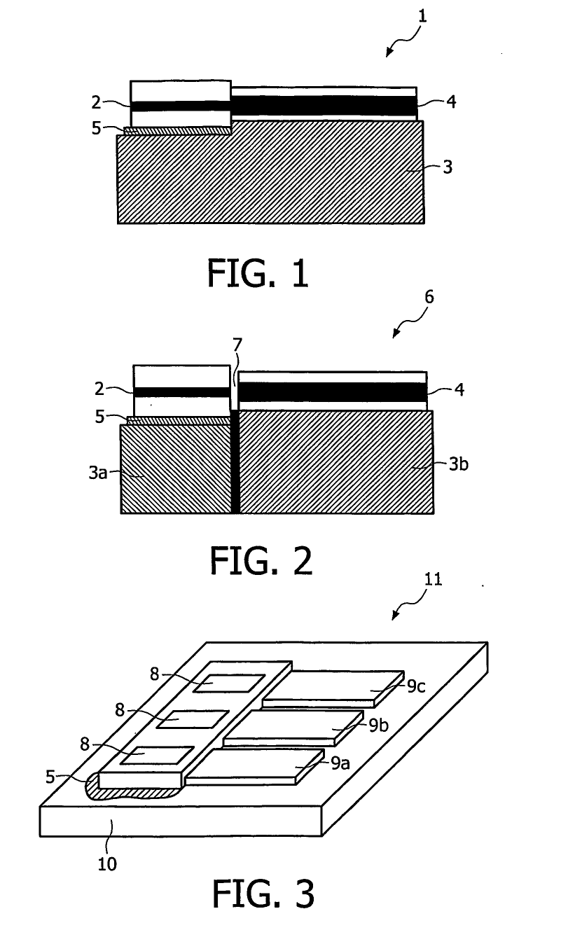

FIG. 1 shows a schematic side view of a waveguide laser located on one substrate;

FIG. 2 shows a schematic side view of a waveguide laser located on two substrates;

FIG. 3 shows a schematic view of a waveguide laser with a laser diode bar of three emitters and three upconversion layers located on one substrate;

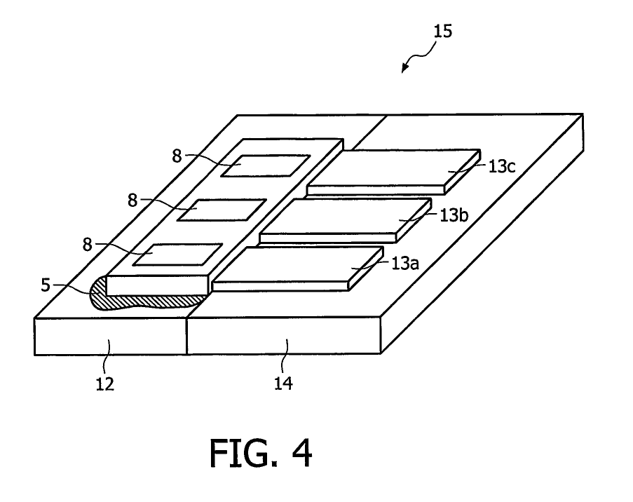

FIG. 4 shows a schematic view of a waveguide laser with a laser diode bar of three emitters and three upconversion layers located on two substrates;

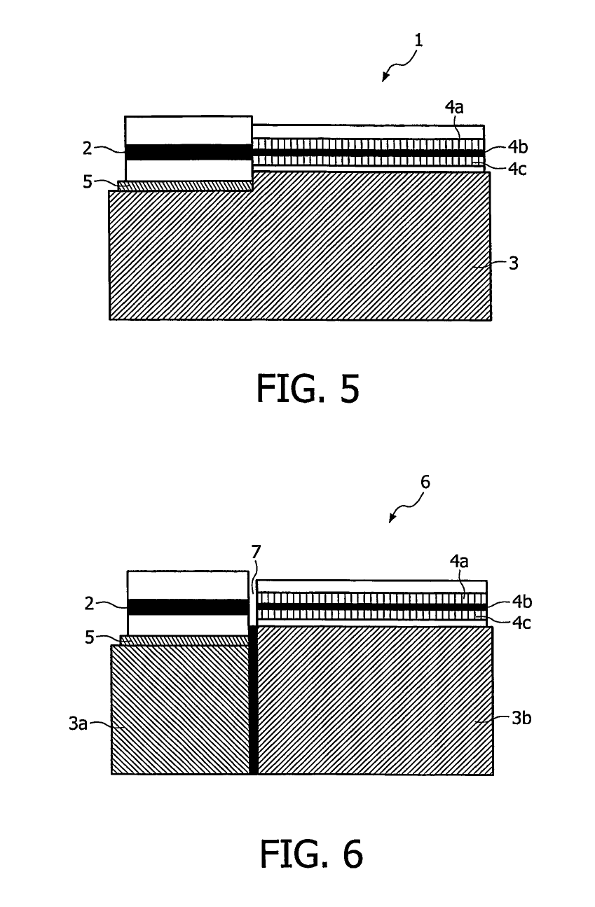

FIG. 5 shows a schematic side view of a waveguide laser located on one substrate in which the upconversion layer is placed between two waveguide layers

FIG. 6 shows a schematic side view of a waveguide laser located on two substrates in which the upconversion layer is placed between two waveguide layers

FIG. 1 shows a schematic side view of a waveguide laser (1) consisting of a laser diode bar (2) that is soldered with a soldering layer (5) to a substrate (3). On the same substrate (3) an upconversion layer (4) is placed. The upconversion layer is of ZBLAN:Er and placed between two layers of lower refractive index e.g. consisting of ZBLAN with a different stoichiometric composition.

FIG. 2 shows a schematic side view of the waveguide laser (6) consisting of a laser diode bar (2) that is soldered with a soldering layer (5) to a first substrate (3a). On a separate second substrate (3b) an upconversion layer (4) of ZBLAN:Er is placed, whereby said upconversion layer is arranged between two layers of lower refractive index e.g. consisting of ZBLAN with a different stoichiometric composition. This second substrate (3b) is positioned adjacent to the first substrate (3a) and between the laser diode bar (2) and the upconversion layer (4) is a gap (7) filled with a material having a index of refraction between the index of refraction of the diode laser bar (2) and the index of refraction of the upconversion layer (4).

FIG. 3 shows a schematic view of a waveguide laser (11) consisting in this case of a laser diode bar of three emitters (8) that is soldered with a soldering layer (5) to a substrate (10) and three upconversion layers (9a; 9b, 9c) placed in front of the emitter output facets on the same substrate (10). In this case, the three individual upconversion lasers (9a; 9b, 9c) emit red (9a), green (9b) and blue light (9c).

According with another embodiment of the present invention a waveguide laser consisting of a laser diode bar of three emitters and three upconversion layers placed in front of the emitter output facets on the same substrate. In this case, the three individual upconversion lasers emit light of only one color. However, a waveguide laser according to the present invention can possess more or less emitters in one device and emit light of one or more colors (in particular also more than three colors)

FIG. 4 shows a schematic view of a waveguide laser (15) consisting of a laser diode bar of three emitters (8) soldered with a soldering layer (5) to a first substrate (12) and three upconversion layers (13a; 13b, 13c) soldered to a separate second substrate (14). The three upconversion layers (13a; 13b, 13c) soldered to said second substrate (14) are placed in front of the emitter output facets of the diode laser bar on the first substrate (12). In this case, the three individual upconversion lasers (13a; 13b, 13c) emit red (13a), green (13b) and blue light (13c).

FIG. 5 shows a schematic side view of a waveguide laser (1) consisting of a laser diode bar (2) that is soldered with a soldering layer (5) to a substrate (3). On the same substrate (3) an upconversion layer (4b) is placed. The upconversion layer is of ZBLAN:Er and placed between two waveguide layers (4a, 4c) of lower refractive index e.g. consisting of ZBLAN with a different stoichiometric composition. The upconversion layer (4b) and the two waveguide layers (4a, 4c) can in turn be placed between two layers of lower refractive index than the waveguide layers, e.g. consisting of ZBLAN with a stoichiometric composition differing from the upconversion layer and the waveguide layer.

FIG. 6 shows a schematic side view of the waveguide laser (6) consisting of a laser diode bar (2) that is soldered with a soldering layer (5) to a first substrate (3a). On a separate second substrate (3b) an upconversion layer (4b) of ZBLAN:Er is placed, whereby said upconversion layer is arranged between two waveguide layers (4a, 4c) of lower refractive index e.g. consisting of ZBLAN with a different stoichiometric composition. The upconversion layer (4b) and the two waveguide layers (4a, 4c) can in turn be placed between two layers of lower refractive index than the waveguide layers, e.g. consisting of ZBLAN with a stoichiometric composition differing from the upconversion layer and the waveguide layer. This second substrate (3b) is positioned adjacent to the first substrate (3a) and between the laser diode bar (2) and the upconversion layer (4) is a gap (7) filled with a material having a index of refraction between the index of refraction of the diode laser bar (2) and the index of refraction of the upconversion layer (4).

However, the waveguide laser of FIG. 4 can be implemented so that the three individual upconversion lasers (13a; 13b, 13c) emit light of only one colour and/or said waveguide laser possess more or less emitters and emit light of one or more colors, in particular more than three colors.

When the diode laser end facet is coated with an end mirror that is partially transmissive in the infrared, the upconversion layer end facet pointing to the IR diode laser end facet is coated with a highly reflective coating in the visible wavelength and highly transmissive in the infrared it is preferred that the gap between the adjacent diode laser and upconversion layer is filled with a material translucent for visible wavelength radiation and/or infrared wavelength radiation whereby the filling material has preferably a index of refraction between the index of refraction of the diode laser or diode laser bar and the index of refraction of the upconversion layer.

More preferably the filling material has an index of refraction not deviating by more than 0.2, preferably by more than 0.1, from the index of refraction of the laser bar or from the index of refraction of the upconversion material or from the index of refraction of the waveguide layer(s).

When the diode laser end facet is coated with an end mirror that is partially transmissive in the infrared and highly reflective in the visible wavelength it is preferred that the gap between the adjacent diode laser and upconversion layer is filled with a material translucent for visible wavelength radiation and infrared wavelength radiation whereby the filling material has a index of refraction that differs not more than 0.2 from the index of refraction of the upconversion layer.

Further, a waveguide laser according to present invention can have:

a length of the upconversion layer that is ≧100 μm and ≦100,000 μm, preferably ≧200 μm more preferably ≧500 μm and most preferably ≧1000 μm ≦50,000 μm; and/or

a width of the upconversion layer that has approximately the same width as the emitting layer of the diode laser, preferably >1 μm wider than the said emitter width, but not more than 200 μm wider than the said emitter width; and/or

a thickness of the upconversion layer or, respectively, the total thickness of the upconversion layer and the two waveguide layers, that is by at least 1 μm thicker than the thickness of the emitting layer of the diode laser, preferably 2 μm thicker than said emitter thickness, but not more than 20 μm thicker than said emitter thickness.

However, the thickness of the upconversion layer or, respectively, the total thickness of the upconversion layer and the two waveguide layers, can be at least 1 μm thicker than the thickness of the emitting layer of the diode laser, preferably at least 1.5 μm thicker than the thickness of the emitting layer of the diode laser and more preferably at least 2 μm thicker than the thickness of the emitting layer of the diode laser. Further, the thickness of the upconversion layer or, respectively, the total thickness of the upconversion layer and the two waveguide layers, can be at least 2.5 μm thicker than the thickness of the emitting layer of the diode laser, at least 3 μm thicker than the thickness of the emitting layer of the diode laser, at least 4 μm thicker than the thickness of the emitting layer of the diode laser or at least 5 μm thicker than the thickness of the emitting layer.

Individual IR diode lasers can be conductively contacted such that each IR diode laser can be controlled separately and/or groups of IR diode lasers are conductively contacted such that a group of IR diode lasers are conjointly operated. For example, a group of IR diode lasers can be a number of IR diode lasers producing the same colour or different colours in the respective upconversion layer(s).

In a preferred embodiment of the present invention a light source is provided comprising a number of waveguide laser groups, whereby a number of red colour, green colour and blue colour emitting waveguide lasers are conjointly operated each allowing a time-sequential operating of waveguide lasers with different colours. This allows for example to adapt the output power of different visible wavelength radiation, i.e. different colours, by varying the electric power of the respective IR diode laser and/or of the conjointly operated IR diode lasers.

Further, an IR diode laser group can also comprise individual IR diode lasers used to pump waveguides, such as upconversion layers, leading to different colours. However, it is preferred that a group of IR diode lasers are used to pump waveguides, such as upconversion layers, leading to the same colour output.

It is further preferred that a number of IR diode laser groups used to pump waveguides of the same colour output can be operated such that each group can be addressed individually.

The individual operating of an IR diode laser, i.e. the IR diode laser is individually conductively contacted, offers the possibility to switch off an IR diode laser which has a malfunction. Furthermore, it allows to avoid shortcuts or unneeded heat generation of IR diode lasers having a malfunction.

It is intended that a waveguide laser of the present invention can be build up such that a diode laser bar or stack is adjacent arranged to at least one upconversion layer. However, a diode laser bar or stack according to the present invention can comprise at least one upconversion layers. In general, each upconversion layer converts the IR wavelength into a specific visible wavelength, preferably to one colour of the primary colours red (R) green (G) or blue (B). The upconversion layers are adjacent arranged on the same or separate substrates to produce a R-G-B pattern and/or the upconversion layers are adjacent arranged to produce an alternating R/G/B or repeating R-G-B pattern.

In the manufacturing process, it is possible to start with one upconversion layer adjacent arranged to a diode laser bar on the same or separate substrates. The lateral structuring of this initially one upconversion layer can be done using one of the known techniques of e.g. lithography, removal by laser ablation, mechanic removal or modification of the refractive index by e.g. ion bombardement or UV treatment.

In a more preferred embodiment an IR laser diode of the present invention comprises one diode laser bar positioned on a substrate and three upconversion layers positioned on the same substrate or on a separate substrate, whereby the laser bar and the three up-converting layers are adjacent arranged to each other, whereby the first upconversion layer having an output of blue light, the second upconversion layer having an output of green light and the third upconversion layer having an output of red light.

Each upconversion layer is positioned in front of one single emitter facet of the diode laser. In case of a diode laser bar, there is thus to each emitter one separate upconversion layer of the same or different material and/or doping (see FIGS. 3 and 4).

To increase the optical power level, at least two upconversion layers can be used when the IR diode laser comprises at least two lasers or a stack of two or more diode laser bars.

An upconversion layer placed between two waveguide layers of lower refractive index, e.g. consisting of undoped ZBLAN with a different stochiometric composition can be bonded in front adjacent to the IR diode laser bar or stack or deposited there, e.g. by pulsed laser deposition (PLD).

Subsequently, the present invention is explained in more detail on an example based on a waveguide laser according to the present invention with upconversion layers having an output of the three primary colors at the wavelengths 455 μm, 544 nm and 635 nm with an IR to visible conversion efficiency for example of 16%, 20% and 10%, respectively.

In a projection display with 1000 screen lumens and an optical efficiency of about 50%, comparable to a white light color balance of D65, a laser light source has to deliver 2.1 W of red (635 nm), 2.2 W of green (544 nm) and 2.4 W of blue light (455 nm). According to optical conversion efficiencies as mentioned above, assuming that for 50 W IR 20 IR diode lasers are used in one bar, whereby 9 IR diode lasers are necessary to convert to red light, 5 IR diode laser are necessary to convert to green light and 6 IR diode laser are necessary to convert to blue light. To achieve exact balancing of the primary colors in the example above it can be necessary that the IR diode laser power of at least one of IR diode lasers used to pump the green and the red lasers may be adjusted slightly reduced compared with the other IR diode lasers used to pump the blue laser. This is achieved for example when the IR diode lasers are contacted either individually and/or all IR diode lasers of the same color output are contacted as one group, as it has been described before. Alternatively, by adapting the green and red output power, the color point can be shifted.

The individually addressed IR diode laser or groups of IR diode lasers used to pump waveguides with an output of one of the primary colors is advantageously for following reasons:

the power levels of the primary colors can be changed individually or by groups

the IR laser diodes can be activated individually or by groups at different times, e.g. in a time sequential mode where in the first time slot red, in the second time slot green and in the third time slot blue light is produced.

This is of advantage in all single panel displays and allows to work without a color wheel or color filter commonly used in combination with white light sources. The length of the time slots may be the same, but it may also be chosen to be different for the primary colors. In the latter case, this allows a further improvement to balance the colors than described above where the power level is adapted. The different power levels can be adapted by choosing a shorter timescale for one primary color with respect to the others to reduce the effective optical power of each color in the projection system.

Another object of the present invention relates to a lighting unit comprising at least one of the waveguide lasers of the present invention being designed for the usage in one of the following applications:—shop lighting,—home lighting,—accent lighting,—spot lighting,—theater lighting,—automotive headlighting,—fiber-optics applications, and—projection systems.

1. A waveguide laser producing visible wavelength radiation from IR wavelength radiation comprising: a) at least one semiconductor diode laser or diode laser bar producing IR wavelength radiation; b) at least one upconversion layer having a thickness of at least 1 μm thicker than the thickness of the emitting layer in the semiconductor diode laser that converts the IR wavelength radiation into visible wavelengths by an upconversion process of photon absorption energy transfer followed by emission; c) at least one optical resonator which recirculates the visible wavelength radiation and/or at least one optical resonator which recirculates the IR wavelength radiation; whereby
the laser diode or laser diode bar and the upconversion layer(s) are arranged on the same substrate or each on a separate substrate;
the laser diode or laser diode bar and the upconversion layer(s) are adjacent arranged, whereby a gap between the adjacent arranged diode laser bar and the upconversion layer(s) is formed; or—the laser diode or laser diode bar and the upconversion layer(s) are contacting arranged in this order; and whereby the waveguide laser has a beam quality M2 of ≧2 and ≦1000.

2. A waveguide laser producing visible wavelength radiation from IR wavelength radiation comprising: a) at least one semiconductor diode laser or laser bar producing IR wavelength radiation; b) at least one upconversion layer that converts the IR wavelength radiation into visible wavelengths by an upconversion process of photon absorption energy transfer followed by emission; c) at least two waveguide layers that carry the IR wavelength radiation; d) at least one optical resonator which recirculates the visible wavelength radiation and/or at least one optical resonator which recirculates the IR wavelength radiation; whereby—the upconversion layer is placed between two waveguide layers of a refractive index smaller than the refractive index of the upconversion layer—the total thickness of the upconversion layer and the two waveguide layers is at least 1 μm thicker than the thickness of the emitting layer in the semiconductor diode laser—the laser diode or laser diode bar and the upconversion layer are arranged on the same substrate or each on a separate substrate;—the laser diode or laser diode bar and the upconversion layer are adjacent arranged, whereby a gap between the adjacent arranged diode laser or diode laser bar and the upconversion layer is formed; or—the laser diode or laser diode bar and the upconversion layer are contacting arranged; and whereby the diode laser has an optical beam quality M2 of ≧2 and ≦1000.

3. The waveguide laser according to claim 1, whereby the semiconductor diode laser bar comprises at least 2, preferably at least 5, more preferably at least 10, most preferably at least 20 single diode laser emitters.

4. A waveguide laser that comprises a stack of at least 2 waveguide lasers according claim 1.

5. A waveguide laser according to claim 1, whereby the diode laser end facet is coated with an end mirror that is partially transmissive in the infrared, the upconversion layer end facet pointing to the IR diode laser end facet is coated with a highly reflective coating in the visible wavelength and highly transmissive in the infrared and the gap between the adjacent diode laser and upconversion layer is filled with a material translucent for visible wavelength radiation and/or infrared wavelength radiation whereby the filling material has preferably a index of refraction between the index of refraction of the diode laser or diode laser bar and the index of refraction of the upconversion layer.

6. The waveguide laser according to claim 1, whereby the diode laser end facet is coated with an end mirror that is partially transmissive in the infrared and highly reflective in the visible wavelength and the gap between the adjacent diode laser and upconversion layer is filled with a material translucent for visible wavelength radiation and infrared wavelength radiation whereby the filling material has index of refraction that differs not more than 0.2 from the index of refraction of the upconversion layer.

7. The waveguide laser according to claim 1, whereby—a length of the upconversion layer that is ≧100 μm and ≦100,000 μm, preferably ≧200 μm, more preferably ≧500 μm and most preferably ≧1000 μm and ≦50,000 μm; and/or—a width of the upconversion layer that has approximately the same width as the emitting layer of the diode laser, preferably >1 μm wider than the said emitter width, but not more than 200 μm wider than the said emitter width; and/or—a thickness of the upconversion layer or, respectively, the total thickness of the upconversion layer and the two waveguide layers, that is by at least 1 μm thicker than the thickness of the emitting layer of the diode laser, preferably 2 μm thicker than said emitter thickness, but not more than 20 μm thicker than said emitter thickness.

8. The waveguide laser according claim 1, whereby the diode laser bar and/or stacks are electro-conductively connected with one p-electrode and one n-electrode, or whereby the single diode laser emitters and/or stacks are electro-conductive connected separated from each other, or as individual groups or common in order to receive a desired activation.

9. The diode laser according to claim 1, whereby the diode laser comprises at least 3, preferably at least 15 upconversion layers, preferably each converts the IR wavelength into one colour of the primary colours red (R) green (G) or blue (B), more preferably the upconversion layers are adjacent arranged to produce a R-G-B pattern or the upconversion layers are adjacent arranged to produce an alternating R/G/B or repeating R-G-B pattern.

10. A lighting unit comprising at least one of the diode laser according to claim 1, being designed for the usage in one of the following applications:
shop lighting,—home lighting,—accent lighting,—spot lighting,—theater lighting,—automotive headlighting,—fiber-optics applications, and—projection systems.
